(19) United States
(12) Patent Application Publication
(10) Pub. No.: US 2006/0157750 A1
(43) Pub. Date: Jul. 20, 2006

(54) Semiconductor device having etch-resistant L-shaped spacer and fabrication method thereof

(75) Inventors: Jong-pyo Kim, Seongnam-si (KR); Young-gun Ko, Seongnam-si (KR); Jong-ho Yang, Seoul (KR)

Correspondence Address: F. CHAU & ASSOCIATES, LLC, 130 WOODBURY ROAD, WOODBURY, NY, 11797, US

(73) Assignee: Samsung Electronics Co., Ltd.

(21) Appl. No.: 11/171,810

(22) Filed: Jun. 30, 2005

Related U.S. Application Data
(60) Provisional application No. 60/645,503, filed on Jan. 20, 2005.

(51) Int. Cl. H01L 21/8234; H01L 29/76; H01L 21/336

(52) U.S. Cl. 257/288; 438/197

(57) ABSTRACT

Provided is a semiconductor device having an etch-resistant L-shaped spacer and a fabrication method thereof. The semiconductor device comprises a semiconductor substrate, a gate insulating layer formed on the semiconductor substrate, a gate electrode formed on the gate insulating layer, an L-shaped lower spacer conformally formed on sidewalls of the gate electrode and a portion of the substrate, an etch-resistant L-shaped spacer conformally formed on the L-shaped lower spacer, low-concentration source/drain regions aligned to sides of sidewall portions of the L-shaped lower spacer and formed within the substrate, and high-concentration source/drain regions aligned to sides of a bottom portions of the etch-resistant L-shaped spacer and formed within the substrate.

### CROSS-REFERENCE TO RELATED APPLICATIONS

This application claims the benefit of U.S. Provisional Application No. 60/645,503 filed Jan. 20, 2005 in the United States Patent and Trademark Office, the disclosure of which is incorporated by reference.

### BACKGROUND OF THE INVENTION

1. Field of the Invention

The present invention relates to a semiconductor device and a fabrication method thereof, and more particularly, to a semiconductor device having an etch-resistant L-shaped spacer and a fabrication method thereof.

2. Description of the Related Art

The trend towards enhancing the performance of electronic devices has led to an increasing demand for highly integrated semiconductor devices. To satisfy this demand, there is a need to reduce the size of the gate electrodes of semiconductor devices (e.g., to a sub 100 nm scale). In particular, it is desirable to develop a semiconductor device and a fabrication method thereof that provide performance enhancements and high integration without compromising the small size of the semiconductor device and device performance. However, the art currently shows that the area for contact formation relative to the source/drain region gradually decreases as the gate electrode features become smaller, thus significantly degrading device performance.

Accordingly, there is a need to develop semiconductor devices having new spacers that can enhance device performance while providing a sufficiently large area for contact formation in scaled-down semiconductor devices.

### SUMMARY OF THE INVENTION

According to an aspect of the present invention, there is provided a semiconductor device comprising a semiconductor substrate, a gate insulating layer formed on the semiconductor substrate, a gate electrode formed on the gate insulating layer, an L-shaped lower spacer conformally formed on the sidewalls of the gate electrode and a portion of the substrate, an etch-resistant L-shaped spacer conformally formed on the L-shaped lower spacer, low-concentration source/drain regions aligned to the sides of sidewall portions of the L-shaped lower spacer and formed within the substrate, and high-concentration source/drain regions aligned to the sides of the bottom portions of the etch-resistant L-shaped spacer and formed within the substrate.

According to another aspect of the present invention, there is provided a method of fabricating a semiconductor device including providing a semiconductor substrate having a gate insulating layer and a gate electrode sequentially stacked thereon, and forming a transistor having an L-shaped lower spacer conformally formed on the sidewalls of the gate electrode and a portion of the substrate, an etch-resistant L-shaped spacer conformally formed on the L-shaped lower spacer, low-concentration source/drain regions aligned to the sides of sidewall portions of the L-shaped lower spacer and formed within the substrate, and high-concentration source/drain regions aligned to the sides of the bottom portions of the etch-resistant L-shaped spacer and formed within the substrate.

### BRIEF DESCRIPTION OF THE DRAWINGS

The present invention will become more apparent by describing in detail exemplary embodiments thereof with reference to the attached drawings in which:

FIGS. 1 through 8 are cross-sectional views illustrating semiconductor devices and fabrication methods thereof according to embodiments of the present invention.

### DETAILED DESCRIPTION OF PREFERRED EMBODIMENTS

The present invention will now be described more fully with reference to the accompanying drawings, in which embodiments of this invention are shown. The present invention and methods of accomplishing the same may be understood more readily by reference to the following detailed description of the embodiments and the accompanying drawings. Like reference numerals refer to like elements throughout the specification.

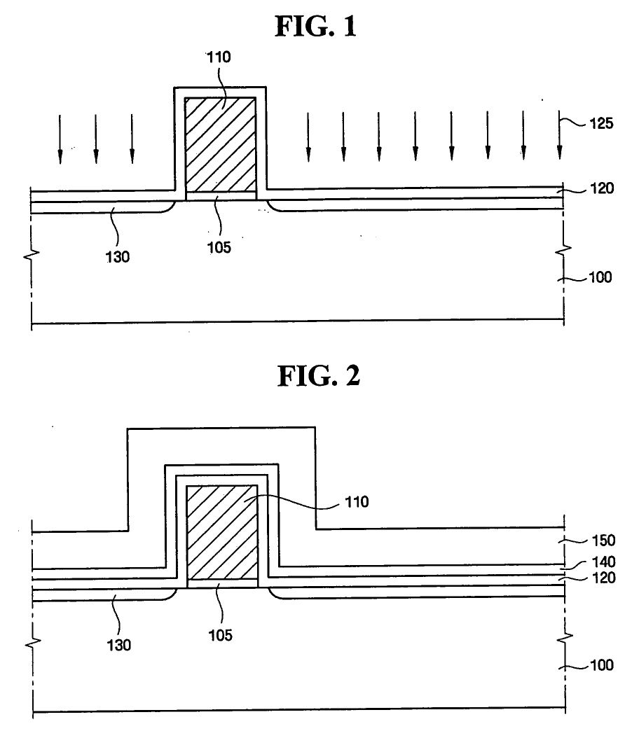

FIGS. 1-8 illustrate methods for fabricating semiconductor devices and semiconductor devices manufactured thereby according to the embodiments of the present invention. As referred to herein, a “semiconductor device” may be any device including, but not limited to, a highly integrated semiconductor memory element such as DRAM, SRAM, flash memory, a micro-electro-mechanical system (MEMS), an optoelectronic device, or a processor such as a CPU or a DSP. In addition, the semiconductor device may include semiconductor elements of the same kind or a single chip data processing element composed of different kinds of semiconductor elements necessary for providing comprehensive functionality, such as a system-on-chip (SOC).

FIG. 1 is a cross-sectional view illustrating a process of forming low concentration source/drain regions 130.

Referring to FIG. 1, a device isolation region (not shown) is first formed within a semiconductor substrate 100 to define an active region, and a gate insulating layer 105 is then formed on the semiconductor substrate 100. A step of forming a well (not shown) may be performed before or after forming the device isolation region.

Useful examples of the substrate 100 include, but are not limited to, a substrate made of at least one semiconductor material selected from the group consisting of Si, Ge, SiGe, GaP, GaAs, SiC, SiGeC, InAs and InP, and an SOI (Silicon-On-Insulator) substrate.

The gate insulating layer 105 may be formed of an oxide layer, a silicon oxide layer formed by thermally oxidizing the substrate 100, SiOxNy, GeOxNy, GeSiOx, silk, polyimide, a material having a high dielectric constant (referred to as a “high-k” material), a combination of these materials, or a stacked layer in which layers of these materials are sequentially stacked. Useful examples of the high-k material include Al₂O₃, Ta₂O₅, HfO₂, ZrO₂, hafnium silicate, and zirconium silicate.

Subsequently, a conductive layer for a gate electrode is formed on the gate insulating layer 105 and patterned to form a gate electrode 110. The gate electrode 110 may be a conductive layer made of impurity-doped polysilicon (poly-Si), tungsten, Si—Ge, Ge, or a stacked layer in which layers of these materials are sequentially stacked. The impurities doped into the polysilicon may be N- or P-type impurities. If these impurities are the same type as that of the transistor that is to be formed, then the transistor performance may be enhanced.

A first insulating layer 120 to be used as a spacer is conformally formed over the entire surface of the substrate 100 having the gate electrode 110 formed thereon. The first insulating layer 120 may be a silicon oxide layer formed by a low temperature chemical vapor deposition (LTCVD) method performed at approximately 400° C., or a silicon oxide layer formed by thermally oxidizing lateral surfaces of the gate electrode 110. The first insulating layer 120 cures damages that occur when etching the gate electrode 110. In addition, the first insulating layer 120 prevents impurities within the gate electrode 110 from contacting outside layers, and prevents the gate electrode 110 from deteriorating in quality due to the difference in the expansion coefficient between the gate electrode 110 and the etch-resistant L-shaped spacer (see LS2 shown in FIG. 4.). Therefore, the first insulating layer 120 may be formed of an oxide.

After forming the first insulating layer 120, impurities 125 are implanted onto the entire surface of the substrate 100 to form low concentration source/drain regions 130.

N-type impurities, e.g., P or As, may be implanted on an NMOS active region, and P-type impurities, e.g., B, may be implanted in a PMOS active region.

To prevent punch-through due to short channel effect, an implantation process may be carried out in an area where impurities of an opposite type from that of the impurities for forming the low-concentration source/drain regions 130. For example, P-type impurities, e.g., B, may be implanted into an NMOS active region and N-type impurities, e.g., P or As, may be implanted into a PMOS active region. This implantation is called halo-ion implantation.

Therefore, the first insulating layer 120 functions to adjust profiles of the low concentration source/drain regions 130 and a halo region (not shown).

FIG. 2 is a cross-sectional view illustrating a process of forming a second and a third insulating layers 140 and 150 to be used as spacers according to an embodiment of the present invention.

Referring to FIG. 2, a second insulating layer 140 and a third insulating layer 150 to be used as a spacer are sequentially formed conformally on the first insulating layer 120.

The second insulating layer 140 may be formed of an etch-resistant material. An etch-resistant material refers to a material that is resistant to damage due to the high dry etching selectivity during the dry etch process of the contact formation process. For example, the dry etching selectivity of the second insulating layer 140 to the contact etch stopper (see 180 shown in FIG. 6) may be greater than or equal to about 1:10.

In addition, the etch-resistant material may be a material that is not damaged even after subjecting to at least one cleaning cycle, which is carried out after forming a spacer and before forming a contact. For example, the second insulating layer 140 may have a wet etching selectivity of greater than or equal to about 1:10 with respect to the third insulating layer 150.

When the contact etch stopper (180 of FIG. 6) is formed of nitride and the third insulating layer 150 is formed of an oxide, a high-k material such as a hafnium-based or a zirconium-based compound or the like is an etch-resistant material that satisfies the above requirements. Other etch-resistant materials include hafnium oxide (HfOx), zirconium oxide (ZrOx), hafnium oxynitride (HfOxNy), zirconium oxynitride (ZrOxNy), hafnium aluminum oxide (HfAlOx), zirconium aluminum oxide (ZrAlOx), hafnium silicon oxide (HfSiOx), zirconium silicon oxide (ZrSiOx), hafnium silicon oxynitride (HfSiOxNy), and zirconium silicon oxynitride (ZrSiOxNy).

The etch-resistant second insulating layer 140 may be formed using CVD or ALD, and when formed in this manner the second insulating layer 140 has superior conformality and uniformity. In addition, since the second insulating layer 140 is formed at a low temperature of approximately 400° C., it exhibits little thermal budget affecting the gate electrode 110. Further, since the second insulating layer 140 is formed of an etch-resistant material, it can be formed to be as thin as from about 30 to about 150 Å. As the second insulating layer 140 becomes thinner, the area for contact formation may increase.

The third insulating layer 150 may also be formed of an oxide using LTCVD.

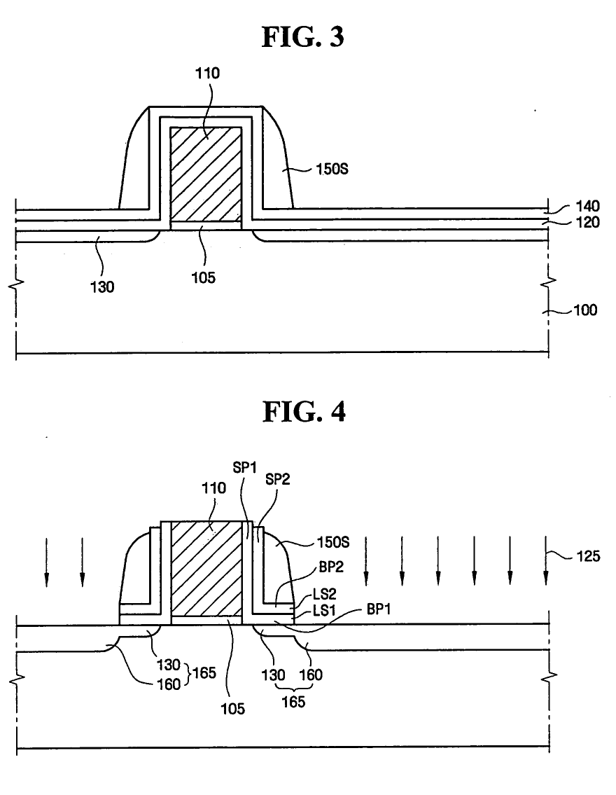

FIG. 3 illustrates a step of forming an upper spacer 150S according to an embodiment of the present invention.

Referring to FIG. 3, the third insulating layer 150 is etched using an etch-back process to form the upper spacer 150S which contacts the sidewalls of the second insulating layer 140 and is used as a spacer.

FIG. 4 is a cross-sectional view illustrating the formation of source/drain regions 165 which are formed to complete a transistor according to an embodiment of the present invention.

Referring to FIG. 4, the second insulating layer 140 and the first insulating layer 120 are sequentially dry etched using the upper spacer 150S as an etch mask to form an etch-resistant L-shaped spacer LS2 and an L-shaped lower spacer LS1. Reactive ion etching (RIE) can be used as the dry etching method.

Each of the L-shaped spacers LS1 and LS2 comprises sidewall portions SP1 and SP2 that are disposed at the sidewalls of the gate electrode 110 and the bottom portions BP1 and BP2 horizontally projecting from the bottom of the sidewall portions.

Subsequently, impurities 125 are implanted to form high concentration source/drain regions 160 using the upper spacer 150S and the L-shaped spacers LS2 and LS1 as an ion implantation mask, thereby completing source/drain regions 165. N-type impurities, e.g., P or As, may be implanted in an NMOS active region, and P-type impurities, e.g., B, may be implanted in a PMOS active region. The impurity concentration and ion implantation energy are greater than those of the low concentration source/drain regions 130.

As a result, the source/drain regions 165 are formed and consist of low concentration source/drain regions 130 and high-concentration source/drain regions 160. The low-concentration source/drain regions are formed within the substrate and are aligned to both sides of the sidewall portion SP1 of the L-shaped lower spacer LS1, while the high-concentration source/drain regions are formed within the substrate and are aligned to both sides of the bottom portion BP2 of the etch-resistant L-shaped spacer LS2.

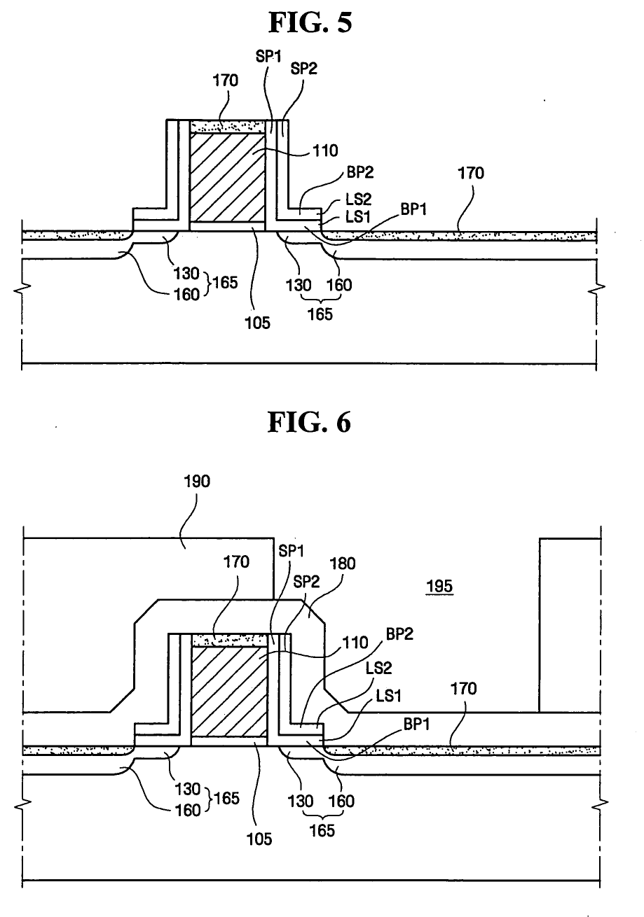

FIG. 5 is a cross-sectional view illustrating a pre-treatment performed prior to the contact formation according to an embodiment of the present invention.

Referring to FIG. 5, the upper spacer 150S is removed through the pre-treatment leaving only the L-shaped spacers LS1 and LS2. The upper spacer 150S is completely removed by at least one cleaning cycle, such as a cleaning step for removing a native oxide layer formed on an active region, before forming the source/drain regions 165, a cleaning step performed after completing the source/drain regions 165, a cleaning step performed after forming a silicide blocking pattern during a silicidation process, and a cleaning step performed before the silicidation process. The cleaning steps may be performed using a hydrofluoric (HF) solution diluted in deionized water, an aqueous fluoride based solution, or a mixed solution of ammonium hydroxide HF and deionized water.

Thus, as shown in FIG. 5, only the L-shaped spacers LS1 and LS2 remain on the sidewalls of the gate electrode 110.

While it is shown in FIG. 5 that a silicide layer 170 is formed on both the gate electrode 110 and the source/drain regions 165, the silicide layer 170 can also be formed only on the gate electrode 110 or only on the source/drain regions 165 according to the performance requirements of the MOS. In addition, in a case where the gate electrode 110 is made of a highly refractive metal such as tungsten, it is not necessary to form a silicide layer on the gate electrode 110.

Since the L-shaped spacer LS2 is made of an etch-resistant material, only the upper spacer 150S is selectively removed through the above-described cleaning steps and the etch-resistant L-shaped spacer LS2 remains robust because it is not damaged in the etching process.

The upper spacer 150S is selectively removed and only the L-shaped spacers LS1 and LS2 remain to provide a wider space for contact formation, thus increasing the area for a subsequent contact formation. The etch-resistant L-shaped spacer LS2 according to an embodiment of the present invention enables a semiconductor device to be more easily scaled down.

FIG. 6 is a cross-sectional view illustrating a process of forming a contact hole 195 according to an embodiment of the present invention.

A contact etch stopper 180 and an interlayer dielectric (ILD) 190 are sequentially formed over the entire surface of the semiconductor substrate having the L-shaped spacers LS1 and LS2 remaining thereon.

The contact etch stopper 180 is formed of a material having a high dry etching selectivity to the etch-resistant L-shaped spacer LS2. For example, the contact etch stopper 180 can be made of nitride.

The ILD 190 is formed of a high density plasma (HDP) oxide layer or a chemical vapor deposition (CVD) oxide layer. The ILD 190 may be planarized by a chemical mechanical polishing (CMP) process.

Subsequently, a mask pattern (not shown) defining a contact is formed, and the ILD 190 is then etched using this mask pattern as an etch mask to form the contact hole 195 exposing a top surface of the contact etch stopper 180.

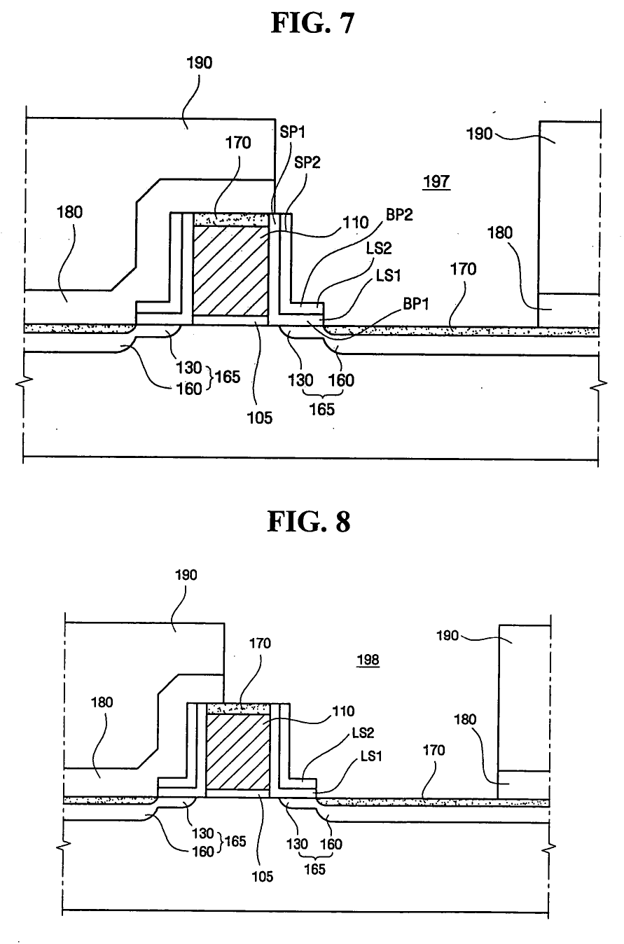

FIG. 7 is a cross-sectional view illustrating a process of forming source/drain contact hole 197 exposing the source/drain regions 165 according to an embodiment of the present invention.

The contact etch stopper 180 exposed by the contact hole 195 is etched by performing a dry etching process, e.g., reactive ion etching (RIE), thereby completing the source/drain contact hole 197 exposing portions of the source/drain regions 165.

When etching the contact etch stopper 180 to form the source/drain contact hole 197, the etch-resistant L-shaped spacer LS2 is not damaged due to the high etching selectivity to the contact etch stopper 180. In addition, a spacer failure, i.e., a spacer opening, is not generated.

Thereafter, the semiconductor device according to an embodiment of the present invention is completed by performing steps of forming a contact structure to fill the contact hole 197, forming wiring that enables electrical signals to be inputted to or outputted from the PMOS/NMOS transistor, forming a passivation layer on the semiconductor substrate, and packaging the semiconductor substrate. These steps are well known to those skilled in the art. These steps are briefly described.

As shown in FIG. 7, the semiconductor device according to an embodiment of the present invention includes a transistor having a gate insulating layer 105 formed on the semiconductor substrate 100, a gate electrode 110 and silicide layer 170 formed on the gate insulating layer 105, an L-shaped lower spacer LS1 conformally formed on the sidewalls of the gate electrode 110 and silicide layer 170, and a portion of the semiconductor substrate 100, etch-resistant L-shaped spacer LS2 conformally formed on the L-shaped lower spacer LS1, and the source/drain regions 165 including the low-concentration source/drain regions 130 aligned to the sides of the sidewall portion SP1 of the L-shaped lower spacer LS1 and formed within the substrate 100, and high-concentration source/drain regions 160 aligned to the sides of the bottom portion BP1 of the etch-resistant L-shaped spacer LS2 and formed within the substrate 100.

Then, the source/drain contact hole 197 is defined such that it enables electrical signals to be inputted to and outputted from the transistor by the contact etch stopper 180. The contact etch stopper 180 exposes portions of the high-concentration source/drain regions 160 and entirely covers a top surface of the gate electrode 110 and silicide layer 170, and partially covers the etch-resistant L-shaped spacer LS2.

Referring to FIGS. 6 and 7, the source/drain contact hole 197 exposes portions of the source/drain regions 160. As shown in FIG. 8, however, a contact etch stopper 180 on the gate electrode 110, may also be partially removed to form a common contact hole 198 exposing both a portion of a source/drain region 160 and the top surface of the silicide layer 170 above the gate electrode 110. As a result, the contact etch stopper 180 covers only one etch-resistant L-shaped spacer LS2.

As described above in the fabrication method of the semiconductor device according to an embodiment of the present invention, the L-shaped spacer LS2 is made of an etch-resistant material, it remains robust; e.g., the L-shaped spacer LS2 is not opened in the dry etching of the contact etch stopper 180 for forming the contact hole 197 or the common contact hole 198.

In addition, the L-shaped spacer LS2 is made of an etch-resistant material, e.g., 150S shown in FIG. 4, which has been formed on the L-shaped spacer LS2, is selectively removed by the cleaning step performed before the contact formation process, and the L-shaped spacer LS2 remains robust, as it is not damaged by the cleaning step.

Further, the L-shaped spacer LS2 according to an embodiment of the present invention is different from the conventional sidewall spacer, e.g., the L-shaped spacer LS2 provides a wider contact formation region. This configuration allows the formation of a smaller semiconductor device. In addition, even if the thickness of the L-shaped spacer LS2 is reduced to a very small level of about 30 to about 150 Å, the L-shaped spacer LS2 is not damaged, further facilitating a contact formation region.

As described above, the semiconductor device according to an embodiment of the present invention employs an L-shaped spacer, a sufficient area for contact formation can be produced, thereby easily reducing the device size. In addition, the L-shaped spacer is made of an etch-resistant material, and it remains robust during the etching process.

Those skilled in the art will appreciate that many variations and modifications can be made to the embodiments without substantially departing from the principles of the present invention. Therefore, the disclosed embodiments of the invention are used in a generic and descriptive sense only and not for purposes of limitation.

What is claimed is:

1. A semiconductor device comprising:
a semiconductor substrate;
a gate insulating layer formed on the semiconductor substrate;
a gate electrode formed on the gate insulating layer;
an L-shaped lower spacer conformally formed on sidewalls of the gate electrode and a portion of the substrate;
an etch-resistant L-shaped spacer conformally formed on the L-shaped lower spacer;
low-concentration source/drain regions aligned to sides of the sidewall portions of the L-shaped lower spacer and formed within the substrate; and
high-concentration source/drain regions aligned to sides of bottom portions of the etch-resistant L-shaped spacer and formed within the substrate.

2. The semiconductor device of claim 1, further comprising a contact etch stopper layer exposing at least a portion of the high-concentration source/drain regions and covering at least a portion of the etch-resistant L-shaped spacer, or exposing at least a portion of the high-concentration source/drain regions and a top surface of the gate electrode and covering at least a portion of the etch-resistant L-shaped spacer.

3. The semiconductor device of claim 2, wherein the contact etch stopper layer is formed of nitride.

4. The semiconductor device of claim 3, wherein a dry etching selectivity of the etch-resistant L-shaped spacer to the contact etch stopper layer is greater than or equal to about 1:10.

5. The semiconductor device of claim 4, wherein a wet etching selectivity of the etch-resistant L-shaped spacer to the contact etch stopper layer is greater than or equal to about 1:10.

6. The semiconductor device of claim 1, wherein the etch-resistant L-shaped spacer is made of material having a high dielectric constant (high-k).

7. The semiconductor device of claim 6, wherein the high-k material is a hafnium-based or a zirconium-based compound.

8. The semiconductor device of claim 1, wherein the etch-resistant L-shaped spacer has a thickness in the range of from about 30 to about 150 Å.

9. A method of fabricating a semiconductor device comprising:
providing a semiconductor substrate having a gate insulating layer and a gate electrode sequentially stacked thereon; and
forming a transistor having an L-shaped lower spacer conformally formed on sidewalls of the gate electrode and a portion of the substrate, an etch-resistant L-shaped spacer conformally formed on the L-shaped lower spacer, low concentration source/drain regions aligned to sides of sidewall portions of the L-shaped lower spacer and formed within the substrate, and high-concentration source/drain regions aligned to sides of bottom portions of the etch-resistant L-shaped spacer and formed within the substrate.

10. The method of claim 9, wherein the forming of the transistor comprises:
forming a first insulating layer to be used as a spacer, the first insulating layer conform to the gate electrode;
forming low-concentration source/drain regions aligned to sides of sidewall portions of the L-shaped lower spacer by implanting impurities in the semiconductor substrate;
forming second and third insulating layers on the first insulating layer to be used as spacers, the second insulating layers being made of an etch resistant material;
forming an upper spacer contacting sidewalls of the second insulating layer by etching the third insulating layer;
forming an etch-resistant L-shaped spacer and an L-shaped lower spacer by sequentially etching the second insulating layer and the first insulating layer using the upper spacer as an etch mask; and
forming high-concentration source/drain regions aligned to sides of bottom portions of the etch-resistant L-shaped spacer.

11. The method of claim 10, further comprising:
performing pre-treatment to remove the upper spacer so that the etch-resistant L-shaped spacer and the L-shaped lower spacer are left on the sidewalls of the gate electrode;
forming a contact etch stopper layer and an interlayer dielectric (ILD) film over the entire surface of the substrate; and
forming a contact hole exposing at least a portion of the high-concentration source/drain regions or a contact hole exposing at least a portion of the high-concentration source/drain regions and a top surface of the gate electrode by dry etching the ILD film and the contact etch stopper layer.

12. The method of claim 11, comprising performing the pre-treatment for at least one cleaning cycle.

13. The method of claim 12, wherein the cleaning cycle is carried out using a hydrofluoric (HF) solution diluted in deionized water, an aqueous fluoride-based solution, or a mixed solution of ammonium hydroxide HF and deionized water.

14. The method of claim 11, wherein a dry etching selectivity of the etch-resistant L-shaped spacer to the contact etch stopper layer is greater than or equal to about 1:10.

15. The method of claim 11, wherein the contact etch stopper layer is formed of nitride.

16. The method of claim 11, wherein in the forming of the contact hole, a wet etching selectivity of the etch-resistant L-shaped spacer to the contact etch stopper layer is greater than or equal to about 1:10.

17. The method of claim 9, wherein the etch-resistant L-shaped spacer is made of a high-k material.

18. The method of claim 17, wherein the high-k material layer is a hafnium-based or a zirconium-based compound.

19. The method of claim 17, wherein the high-k material layer is formed by chemical vapor deposition or atomic layer deposition.

20. The method of claim 17, wherein the high-k material layer is formed to a thickness in the range of about 30 to about 150 Å.
